(19) United States
(12) Patent Application Publication
(10) Pub. No.: US 2015/0247238 A1
(43) Pub. Date: Sep. 3, 2015

(54) RF CYCLE PURGING TO REDUCE SURFACE ROUGHNESS IN METAL OXIDE AND METAL NITRIDE FILMS

(71) Applicant: Lam Research Corporation, Fremont, CA (US)

(72) Inventors: Frank L. Pasquale, Tualatin, OR (US); Shankar Swaminathan, Beaverton, OR (US); Hu Kang, Tualatin, OR (US); Adrien LaVoie, Newberg, OR (US)

(73) Assignee: Lam Research Corporation, Fremont, CA (US)

(21) Appl. No.: 14/195,653

(22) Filed: Mar. 3, 2014

(51) Int. Cl. C23C 16/44; C23C 16/505; C23C 16/52; H01L 21/02

(52) U.S. Cl. CPC C23C 16/4408; H01L 21/02274; H01L 21/02205; H01L 21/02186; C23C 16/505; C23C 16/52

(57) ABSTRACT

Methods of reducing particles in semiconductor substrate processing are provided herein. Methods involve performing a precursor-free radio frequency cycle purge without a substrate in the process chamber by introducing a gas without a precursor into the process chamber through the showerhead and igniting a plasma one or more times after a film is deposited on the substrate by introducing a vaporized liquid precursor to the process chamber.

### BACKGROUND

Various thin film layers for semiconductor devices may be deposited with plasma-based processes including plasma-enhanced atomic layer deposition (PEALD). However, the deposition process may produce particles that may be deposited on a film, thereby causing defects in the semiconductor device.

### SUMMARY

Provided herein are methods of processing semiconductor substrates. One aspect involves a method of processing semiconductor substrates in a process chamber with a showerhead by: after depositing a film on one or more substrates in the process chamber, performing a precursor-free radio frequency (RF) cycle purge without a substrate in the process chamber by introducing a gas without a precursor into the process chamber through the showerhead and igniting a plasma one or more times, where depositing the film includes introducing a vaporized liquid precursor into the process chamber through the showerhead.

In some embodiments, the methods may be used in deposition of metal oxide or metal nitride films. An example of such a film is titanium oxide, with an example of a vaporized liquid precursor being tetrakis(dimethylamino)titanium (TDMAT), or titanium isopropoxide. In some embodiments, the vaporized liquid precursor has a viscosity greater than about 10 cP. In various embodiments, the gas introduced to the chamber during the RF cycle purge is or includes nitrogen (N₂), helium (He), hydrogen (H₂), nitrous oxide (N₂O) and oxygen (O₂). In some embodiments, the substrate is processed at a chamber pressure between about 1 Torr and 4 Torr. In some embodiments, the substrate is processed at a temperature between about 50° C. and about 400° C.

In various embodiments, the plasma ignited may be a single or dual radio frequency plasma. Single frequency plasmas are typically, though not necessarily, high frequency (HF)-only, with dual frequency plasmas typically including a low frequency (LF) component as well. Example HF powers per substrate area are between about 0.018 W/cm² and about 0.884 W/cm² and example LF powers per substrate area are between about 0 W/cm² and about 0.884 W/cm². In many embodiments, the gas is introduced for between about 0.25 seconds and about 10 seconds. In some embodiments, the plasma is ignited for a time between about 0.25 seconds and about 10 seconds.

In many embodiments, the RF cycle purge may be performed after a plasma-based deposition process. In some embodiments, the RF power of the plasma ignited while performing the precursor-free RF cycle purge is the same as a RF power of the plasma ignited while depositing the film.

Another aspect involves an apparatus for processing semiconductor substrates that includes: a process chamber having one or more stations that include a showerhead and a pedestal; one or more gas inlets into the process stations and associated flow-control hardware; a radio frequency (RF) generator; and a controller having at least one processor and a memory, such that the at least one processor and the memory are communicatively connected with one another, the at least one processor is at least operatively connected with the flow-control hardware and RF generator, and the memory stores computer-executable instructions for: after introducing a vaporized liquid precursor to the process chamber, introducing a gas without a precursor into the process chamber through a showerhead, and igniting a plasma.

In some embodiments, the plasma is ignited by a high frequency power per substrate area of between about 0.018 W/cm² and about 0.884 W/cm² and a low frequency power per substrate area of between of about 0 W/cm² and about 0.884 W/cm². In many embodiments, the gas includes one or more of N₂, He, H₂, N₂O and O₂. In some embodiments, the gas is selected from the group consisting of nitrogen (N₂), helium (He), hydrogen (H₂), nitrous oxide (N₂O), and oxygen (O₂). In some embodiments, the vaporized liquid precursor is TDMAT.

In some embodiments, the gas is introduced for between about 0.25 seconds and about 10 seconds. In various embodiments, the plasma is ignited for a time between about 0.25 seconds and about 10 seconds.

These and other aspects are described further below with reference to the drawings.

### BRIEF DESCRIPTION OF THE DRAWINGS

FIGS. 1-6 are schematic illustrations of substrates in an example of a double patterning scheme.

FIGS. 7A and 7B are process flow diagrams of methods in accordance with disclosed embodiments.

FIG. 8 illustrates a reaction chamber for practicing a method according to disclosed embodiments.

FIG. 9 illustrates a multi-tool apparatus that may be used for practicing a method according to disclosed embodiments.

FIGS. 10A and 10B and 11A and 11B depict atomic force microscopy results of wafers processed in accordance with disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

The terms “semiconductor wafer,” “wafer,” “substrate,” “wafer substrate,” and “partially fabricated integrated circuit” are used interchangeably. “Partially fabricated integrated circuit” can refer to a silicon or other semiconductor wafer during any of many stages of integrated circuit fabrication thereon. A wafer or substrate used in the semiconductor device industry typically has a diameter of 200 mm or 300 mm, though the industry is moving towards the adoption of 450 mm diameter substrates. The flow rates and power levels provided herein are appropriate for processing on 300 mm substrates. One of ordinary skill in the art would appreciate that these flows may be adjusted as necessary for substrates of other sizes. Power levels and flow rates generally scale linearly with the number of stations and substrate area. The flow rates and powers may be represented on a per area basis, e.g., 2500 W may also be represented as 0.884 W/cm². In addition to reaction chambers used to deposit films on semiconductor wafers, other types of deposition reactors may take advantage of the disclosed embodiments. Other types of reactors that may benefit from the disclosed embodiments include those used to fabricate various articles such as printed circuit boards, displays, and the like. In addition to semiconductor wafers, the methods and apparatus described herein may be used with deposition chambers configured for other types of substrates including glass and plastic panels.

Various aspects disclosed herein pertain to methods of processing a semiconductor substrate. Many of these methods may be performed before or after depositing a film on a semiconductor surface, which may involve plasma-activated surface-mediated reactions in which a film is grown over multiple cycles of reactant adsorption and reaction. For example, some films may have been deposited by conformal film deposition (CFD) reactions in which one or more reactants adsorb to the substrate surface and then react to form a film on the surface of the substrate by interaction with plasma. In many CFD processes, the substrate is processed in a reaction chamber with a pedestal and a showerhead. Precursors or reactants may flow from the precursor source through the showerhead and into the chamber. In some CFD and atomic layer deposition (ALD) processes, viscous precursors, or vaporized liquid precursors, may be used, such as tetrakis(dimethylamino)titanium (TDMAT). Viscous precursors may also be used in plasma enhanced chemical vapor deposition (PECVD) processes.

A continuing concern in semiconductor substrate processing is the quality of the deposited film. Defects, such as defects caused by particles, are of particular concern. As semiconductor devices shrink, the effect of a small particle increases and the presence of particles on a deposited film of a substrate may cause the semiconductor device to be defective. Provided herein are methods of reducing particle contamination of a deposited film. The deposited film may be a metal oxide or metal nitride layer in some embodiments. Examples of metal oxides and nitrides include titanium nitride and titanium oxide, as well as oxides and nitrides of aluminum, titanium, hafnium, tantalum, tungsten, manganese, magnesium, or strontium.

Viscous or vaporized liquid precursors may be characterized as precursors that are liquids at about room temperature. Viscous precursors or reactants that flow through the showerhead into the chamber during deposition may condense in the showerhead and on the showerhead sidewalls. As a second precursor or reactant enters the showerhead to flow into the chamber and react with the surface adsorbed first precursor on the substrate surface, particles of the condensed first precursor or reactant may also react with the second precursor or reactant, particularly when the plasma is initiated. Small particles of the material to be deposited, such as titanium oxide, may then be formed in the showerhead or in the chamber space. These small particles may then enter the chamber as the carrier gas or reactants flow into the chamber in subsequent processing steps, and the particles may land on the deposited film on the substrate, causing potential defects. Particles may be embedded in the deposited film as each layer is formed through the deposition steps.

The presence of particles on a semiconductor substrate also contributes to the surface roughness of the substrate. Surface roughness of a wafer may be evaluated by the root mean square (RMS) of the vertical deviations of the roughness profile from the mean line. The larger the RMS roughness of a wafer, the rougher the surface is on the wafer. In conventional ALD or CFD deposition of metal nitrides and metal oxides, the RMS roughness may range from between about 3 Å to as high as about 30 Å if deposited with high plasma power. As devices shrink, film roughness becomes a larger problem, particularly in spacer and hardmask applications for multiple patterning, such as in double patterning or quadruple patterning. Using a spacer or hardmask with higher surface roughness increases surface roughness of the subsequent layers etched using the spacer or hardmask as a mask, which may cause the overall semiconductor device to be defective.

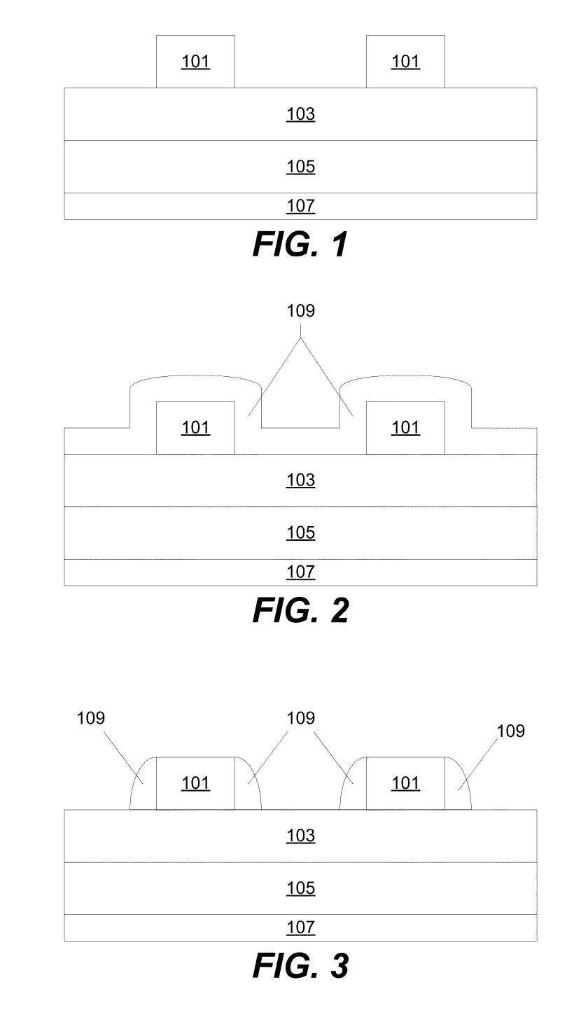

An example of a double patterning scheme that may use the methods disclosed herein is provided in FIGS. 1-6. FIG. 1 provides a schematic illustration of an example of various layers that may be included in a multi-layer stack, such as on a wafer suitable for semiconductor processing. The multi-layer stack in FIG. 1 includes a lithographically defined or patterned first core layer 101 on top of an underlayer 103, which may be a second core layer. The second core layer 103 may be a layer deposited on top of a target layer 105. In some schemes, one or more additional layers may be disposed between the first core layer 101 and the second core layer 103. One of ordinary skill in the art will appreciate that a multi-layer stack suitable for semiconductor processing such as described below may also include other additional layers, such as etch stop layers, cap layers, and other underlayers.

The core layer 101 may be highly etch selective to other materials in the stack, such as silicon and/or silicon-based oxides or nitrides, for example, and may be transparent. The core layer 101 may be a photoresist or may be made of amorphous carbon material or amorphous silicon material. The core layer 101 may be deposited on top of the second core layer 103 by a deposition technique, such as plasma-enhanced chemical vapor deposition (PECVD), and the deposition technique may involve generating a plasma in the deposition chamber from deposition gases including a hydrocarbon precursor. The hydrocarbon precursor may be defined by the formula CₓH_{y}, where x is an integer between 2 and 10, and y is an integer between 2 and 24. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈). A dual radio frequency (RF) plasma source including a high frequency (HF) power and a low frequency (LF) power may be used.

Under the second core layer 103 is the target layer 105. The target layer 105 may be the layer ultimately to be patterned. The target layer 105 may be a semiconductor, dielectric or other layer and may be made of silicon (Si), silicon oxide (SiO₂), silicon nitride (SiN), or titanium nitride (TiN), for example. The target layer 105 may be deposited by ALD, plasma-enhanced ALD (PEALD), chemical vapor deposition (CVD), or other suitable deposition technique.

In FIG. 2, a conformal film 109 is deposited over first core layer 101. The conformal film 109 may also be referred to as a “spacer” and may be deposited to conform to the shape of the pattern on the multi-layer stack to make an evenly distributed layer over the pattern. The conformal layer has a high etch selectivity to the core.

The spacer 109 may be an oxide, such as titanium oxide (TiO₂), or may be a nitride, such as silicon nitride (SiN). The spacer 109 may also be made of dielectric material, such as silicon oxide (SiO₂). In some embodiments, the spacer 109 is made of denser material to withstand more “passes” of patterning and may be deposited by ALD, PEALD, or CFD methods. ALD processes use surface-mediated deposition reactions to deposit films on a layer-by-layer basis. In one example ALD process, a substrate surface, including a population of surface active sites, is exposed to a gas phase distribution of a first film precursor (P1). Some molecules of P1 may form a condensed phase atop the substrate surface. The reactor is then evacuated to remove gas phase P1 so that only adsorbed species remain. A second film precursor (P2) is then introduced to the reactor so that some molecules of P2 adsorb to the substrate surface. The reactor may again be evacuated, this time to remove unbound P2. Subsequently, thermal energy provided to the substrate activates surface reactions between adsorbed molecules of P1 and P2, forming a film layer. Finally, the reactor is evacuated to remove reaction by-products and possibly unreacted P1 and P2, ending the ALD cycle. Additional ALD cycles may be included to build film thickness. In an example of a PEALD process, a plasma is initiated while the second film precursor P2 is introduced to the reactor to activate the reaction between P1 and P2.

CFD may be used to deposit the spacer 109. Generally, CFD does not rely on complete purges of one or more reactants prior to reaction to form the spacer 109. For example, there may be one or more reactants present in the vapor phase when a plasma (or other activation energy) is struck. Accordingly, one or more of the process steps described in an ALD process may be shortened or eliminated in an example CFD process. Further, in some embodiments, plasma activation of deposition reactions may result in lower deposition temperatures than thermally-activated reactions, potentially reducing the thermal budget of an integrated process. For context, a short description of CFD is provided. The concept of a CFD “cycle” is relevant to the discussion of various embodiments herein. Generally a “cycle” is the minimum set of operations used to perform a surface deposition reaction one time. The result of one cycle is production of at least a partial film layer on a substrate surface. Typically, a CFD cycle will include only those steps necessary to deliver and adsorb each reactant to the substrate surface, and then react those adsorbed reactants to form the partial layer of film. Of course, the cycle may include certain ancillary steps such as sweeping one or more of the reactants or byproducts and/or treating the partial film as deposited. Generally, a cycle contains only one instance of a unique sequence of operations. As an example, a cycle may include the following operations: (i) delivery/adsorption of reactant A, (ii) delivery/adsorption of reactant B, (iii) sweep B out of the reaction chamber, and (iv) apply plasma to drive a surface reaction of A and B to form the partial film layer on the surface.

The following conditions are examples of conditions suitable depositing a titanium oxide conformal layer 109 by a CFD process. Deposition may occur at a temperature between about 50° C. and about 400° C., at a pressure between about 0.5 Torr and about 10 Torr, and an RF power for four 300 mm stations between about 100 W and about 2500 W. For a titanium oxide spacer 109, process gases that may be used include, as a titanium source, a titanium amide (e.g., TDMAT), and, as an oxygen source, oxygen or nitrous oxide, separately or together, diluted with an inert carrier gas, for example argon or nitrogen. Process gas flow rates may be as follows: for titanium precursor (TDMAT), between about 0.2 sccm and about 2.0 sccm; for oxygen precursor (O₂, N₂O), between about 5000 sccm and 10,000 sccm, for example N₂O at 5000 sccm; and for the carrier gas (Ar or N₂), between about 0 and 10,000 sccm, for example about 5000 sccm Ar. After or during deposition of the spacer 109, particles (not shown) from the showerhead or in the chamber may be deposited on top of the deposited spacer 109, thereby increasing roughness on the surface of spacer 109. In some embodiments, the conformal layer 109 may be deposited as a silicon oxide layer by CFD using a silicon source such as bis(tertiarybutylamino)silane (SiH₂(NHC(CH₃)₃)₂ (BTBAS).

In FIG. 3, the spacer 109 is etched back or planarized to expose the first core layer 101. After the spacer 109 is etched back, embedded particles may still be in the layer, such as those that were deposited between each layer of CFD in FIG. 2. In various embodiments, the substrate may be planarized at a temperature between about 10° C. and about 60° C. and at a pressure between about 5 mTorr and about 100 mTorr.

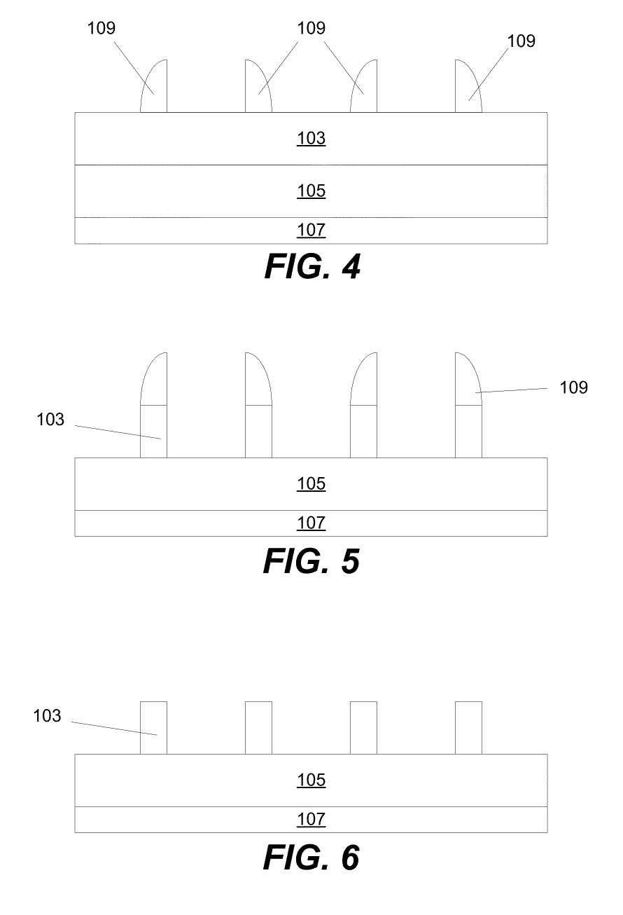

In FIG. 4, the first core layer 101 is stripped or etched, leaving free-standing spacers 109 on the substrate. If the first core layer 101 is a photoresist, it may be etched by flowing oxygen (O₂) at a flow rate between about 100 sccm and about 200 sccm at a temperature between about 40° C. and about 60° C. in a pressure between about 5 mTorr and about 20 mTorr.

If first core layer 101 is made of amorphous carbon material, first core layer 101 may be stripped or etched using an ashing method. An ashing method may be dependent on chemical reactions for material removal, rather than directional movement of energetic ions. For example, any surface that is exposed to the process gas used in an ashing operation may experience material removal due to the exposure, so the AHM material used in the core and under the block mask may have high etch selectivity to the spacer such that the spacer is not etched while the AHM layers are ashed. Additionally, in contrast to some chemical etching processes, ashing operations may produce a reaction product that is completely in the gas phase. Ashing operations for carbon films may, for example, utilize dissociated hydrogen (H₂) or oxygen (O₂) as a process gas, which may react with carbon films to form such gas-phase reaction byproducts.

In FIG. 5, the second core layer 103 is etched down using the patterned spacer 109 as a mask, thereby transferring the pattern to the second core layer 103. If the quality of the free-standing spacers 109 is decreased by the presence of particles in the film, then the second core layer 103 would also have defects. The second core layer 103 may be etched at a temperature between about 50° C. and about 70° C. in a pressure between about 5 mTorr and about 10 mTorr using chemistry suitable for etching the second core layer 103 but not the spacer 109. The second core layer 103 is highly etch selective to the spacer 109. The second core layer 103 may be an amorphous carbon layer, amorphous silicon layer, or a photoresist, such as poly(methyl methacrylate) poly(methyl glutarimide) (PMGI) or phenol formaldehyde resin.

In FIG. 6, the spacer 109 is etched or otherwise removed, leaving the patterned second core layer 103. In one example, the spacer may be removed by flowing CHF₃ and/or CF₄, which may be flowed at flow rates of about 30 sccm to about 50 sccm, and about 50 sccm to about 100 sccm, respectively, at a temperature between about 50° C. and about 70° C., and a pressure between about 2 mTorr and about 20 mTorr.

While a double patterning scheme is described above, the methods described herein may be implemented in higher order patterning schemes, including quadruple or “quad” patterning.

In a patterning scheme, spacers and etch masks are often used as templates in subsequent integration to precisely form patterns in underlayers and target layers. Since metal oxide and metal nitride layers are often used in spacers or etch masks, metal oxide and metal nitride layers should have low surface roughness and few defects to maintain the patterned structure and withstand various integration conditions. Generating smooth films is advantageous because the resulting integration is directly correlated to the roughness of the patterning or mask material.

Many metal oxide or metal nitride layers may be deposited by introducing a viscous precursor during deposition as described above. Further, other types of films may be deposited by introducing a viscous precursor. The methods disclosed herein may be useful during deposition of any type of film that uses a vaporized viscous precursor. As used herein the term “viscous precursor” refers to a precursor having a dynamic viscosity of at least about 10 centipoise (cP), or at least about 20 cP.

During deposition, some of the viscous precursor may condense in the showerhead or adhere to the showerhead walls, such that when a second precursor is introduced and plasma is ignited, particles form and may subsequently land on the deposited metal oxide or metal nitride films, thereby reducing the quality of the films. For example, the presence of particles in a mask film may lead to poor critical dimension nonuniformity after etch of the deposited film, or may increase the roughness of the edges or surface of a patterned mask.

The methods of deposition of metal oxide or metal nitride films described below reduce surface roughness. Reduced surface roughness in deposited films enables spacers and mask films to maintain a pattern as free-standing structures during patterning processes. In particular, the improved surface uniformity also increases the quality of the films such that, once patterned, they may withstand subsequent etching and patterning processes without degrading.

To maintain a clean chamber for processing substrates, some methods involve preventative maintenance, such as changing the showerhead, or administering a wet clean of the chamber. However, conventional methods of reducing or eliminating particles from deposited semiconductor substrates may result in lower throughput due to maintenance or lowered efficiency.

Provided herein are methods of processing semiconductor substrates and reducing particle deposition on substrates without substantially decreasing wafer throughput. Methods involve RF cycle purging at various times during the semiconductor device fabrication process. The methods described herein may also be advantageous with any deposition of any conformal or blanket film using viscous precursors. While the methods may be particularly useful for plasma-based depositions using CFD, PEALD, or PECVD, they may also be used for reducing particle contamination in deposition of films by non-plasma based processes such as thermal ALD and CVD, particularly if the deposition chambers are equipped with plasma sources.

While a warmer showerhead may be warm enough to vaporize the condensed drops of liquid from the viscous precursor, which may reduce the presence of particles in the showerhead, showerheads at room temperature or temperatures cooler than at room temperature may be particularly susceptible to accumulating particles during deposition of films using viscous precursors. Thus, RF cycle purging methods as described herein may be most applicable to purging particles from showerheads at room temperature or temperatures colder than room temperature.

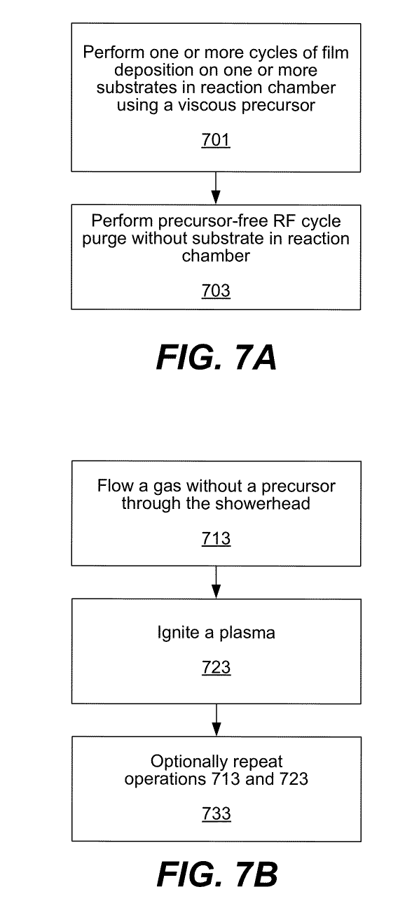

FIGS. 7A and 7B are process flow diagrams of methods of processing semiconductor substrates in a reaction chamber to reduce particles. For the operations in FIG. 7A and 7B, the chamber may have a chamber pressure and pedestal temperature that is the same as the chamber pressure and pedestal temperature during film deposition. Examples of chamber pressure include between about 0.1 Torr to about 100 Torr, for example between about 1 Torr and 4 Torr. In many embodiments, the chamber, station, reactor, or tool is operated at about room temperature, or between about 50° C. and about 400° C. In many embodiments, the showerhead is unheated. While it may be efficient to maintain the chamber pressure and temperature at the deposition conditions, these parameters may also be changed as appropriate for the RF cycle purge.

In operation 701, a film may be deposited on the substrate, such as a metal oxide or metal nitride layer. The film may have been deposited using PEALD by flowing a first vaporized viscous precursor, such as TDMAT, in a first dose through the showerhead and into the chamber, purging the chamber, flowing a second precursor while initiating a plasma, purging the chamber, and repeating these steps for one or more cycles. The substrate may then be removed from the reaction chamber, such as by indexing the wafers in the deposition tool.

Other examples of precursors that may be used in operation 701 for deposition of metal-containing films include STAR-Ti™ (Air Liquide) and TTIP (titanium isopropoxide), or a precursor with a viscosity greater than about 10 cP.

In operation 703, a precursor-free RF cycle purge may be performed without the substrate in the process chamber by introducing a gas without a precursor into the process chamber through the showerhead and igniting a plasma one or more times. In some embodiments, operation 701 may last between about 0.25 seconds and about 10 seconds, or about 0.5 seconds. Operation 703 may be conducted by performing the operations in FIG. 7B in some embodiments. In operation 713 of FIG. 7B, a gas may be flowed without a precursor through the showerhead and into the process chamber. In many embodiments, the gas introduced into the process chamber without a precursor is a carrier gas. Example carrier gases include nitrogen (N₂), helium (He), hydrogen (H₂), oxygen (O₂), and others. The carrier gas may be flowed at a flow rate between about 500 sccm and about 10,000 sccm. The flowing of the carrier gas may electrostatically chuck any particles from the showerhead and into the chamber. In some embodiments, operation 713 may last between about 0.25 seconds and about 5 seconds, or about 0.5 seconds. Introducing a gas without a precursor through the showerhead electrostatically “chucks” any particles from the showerhead.

In operation 723, a plasma may be ignited using a single frequency or dual frequency plasma source. The plasma may be ignited immediately after a short precursor-free “dose” in operation 713 to thereby activate the chucked particles to be purged out of the chamber. In some embodiments, the plasma may be ignited using a high frequency (HF) component only. In some embodiments, the plasma may be ignited one or more times using a dual frequency RF plasma that includes both a HF component and a low frequency (LF) component. Ranges of plasma power may be, for example, between about 50 W and 2500 W for HF power and between about 0 W and 2500 W for LF power for 300 mm substrates in a 4-station tool. Plasma power per substrate area for HF power may be between about 0.018 W/cm² and about 0.884 W/cm² and power per substrate area for LF power may be between about 0 W/cm² and about 0.884 W/cm². In some embodiments, operation 723 may last between about 0.25 seconds and about 10 seconds, or about 0.5 seconds. In many embodiments, the gas continues to flow during the plasma initiation. In some embodiments, the plasma is ignited before the gas flow. In some embodiments, the plasma is ignited after the gas flow. In operation 733, operations 713 and 723 may be repeated for one or more times, or the gas in operation 713 may be continuously flowed while the plasma is ignited in pulses in operation 723. In various embodiments, the gas is continuously flowed while the plasma is ignited in pulses of between about 0.25 seconds and about 10 seconds, or about 0.5 seconds per pulse. It should be understood that the parameters above including flow rates, plasma power, and pulse times may be modified according to particular implementations. In some implementations, the RF cycle purge may end with a purge operation in which a gas is flowed through the chamber after the plasma is extinguished.

Returning to operation 703 of FIG. 7A, the RF cycle purge is performed without a substrate in the reaction chamber. A substrate is a solid piece of material that may be inserted and removed from the reaction chamber, which is not part of the reaction chamber, upon which film is deposited, and upon which film deposition is generally desired. In the context of semiconductor device fabrication, a semiconductor wafer (with or without film(s) deposited thereon) is a typical substrate. In many cases, substrates are disc-shaped and have a diameter of, for example, 200, 300 or 450 mm. Substrates typically go through many rounds of processing to become semiconductor devices. Certain other substrates, however, are not intended to become fully functioning devices. These substrates may be referred to as dummy wafers, and they may be used as test vehicles for evaluating a deposition process or as sacrificial substrates for equilibrating a reaction chamber, for example. It is possible that operation 703 in FIG. 7A may be performed with a dummy wafer or other object in the reaction chamber that is not intended to become a fully functioning device.

In various embodiments, in FIG. 7A, operation 703 is performed before each new wafer is processed, or every 8 wafer depositions, or more frequently between depositions. In some embodiments, each wafer undergoes about 70 deposition cycles at one station of a multi-station tool. Operation 703 may be performed as appropriate during deposition on a wafer or between wafers.

Apparatus

Deposition techniques provided herein may be implemented in a plasma enhanced chemical vapor deposition (PECVD) reactor or a conformal film deposition (CFD) reactor. Such a reactor may take many forms and may be part of an apparatus that includes one or more chambers or reactors, sometimes including multiple stations, that may each house one or more wafers and may be configured to perform various wafer processing operations. The one or more chambers may maintain the wafer in a defined position or positions (with or without motion within that position, e.g., rotation, vibration, or other agitation). In one implementation, prior to operations performed in disclosed embodiments, a wafer undergoing film deposition may be transferred from one station to another within a reactor chamber during the process. For example, a wafer may enter one station for deposition of a conformal film, and then the wafer may be transferred out of that station and into another station for subsequent processing. In other implementations, the wafer may be transferred from chamber to chamber within the apparatus to perform different operations. While in process, each wafer may be held in place by a pedestal, wafer chuck, and/or other wafer-holding apparatus. In some processes a dummy wafer may be held in place by a pedestal. A Vector™ (e.g., C3 Vector) or Sequel™ (e.g., C2 Sequel) reactor, produced by Lam Research Corp. of Fremont, Calif., are both examples of suitable reactors that may be used to implement the techniques described herein. In some implementations, there may be no wafers in each of the chambers of the reactor during operations of disclosed embodiments.

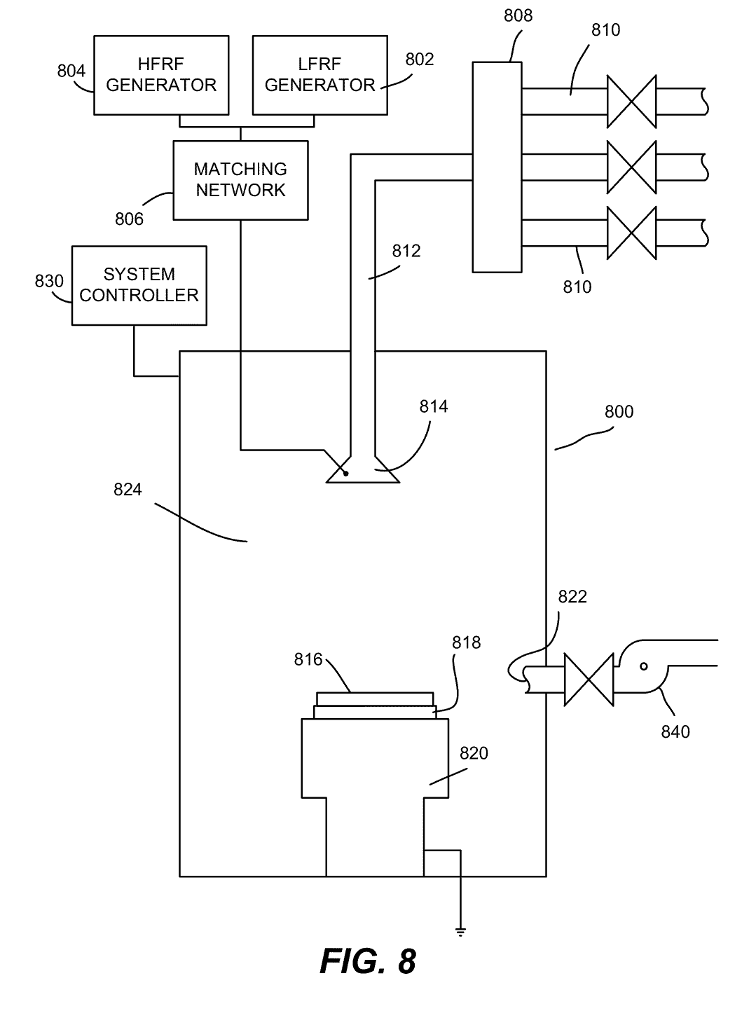

FIG. 8 provides a simple block diagram depicting various reactor components arranged for implementing methods described herein. As shown, a reactor 800 includes a process chamber 824 that encloses other components of the reactor 800 and serves to contain plasma generated by a capacitive-discharge type system including a showerhead 814 working in conjunction with a grounded heater block 820. A high frequency (HF) radio frequency (RF) generator 804 and a low frequency (LF) RF generator 802 may be connected to a matching network 806 and to the showerhead 814. The power and frequency supplied by matching network 806 may be sufficient to generate a plasma from process gases supplied to the process chamber 824. In a typical process, the HFRF component may generally be between 5 MHz to 60 MHz, e.g., 13.56 MHz. In operations where there is an LF component, the LF component may be from about 100 kHz to 5 MHz, or 100 kHz to 2 MHz, e.g., 430 kHz.

Within the reactor, a wafer pedestal 818 may support a substrate 816. In some embodiments, substrate 816 may be a dummy wafer or object that is not intended to become a fully functioning device. The wafer pedestal 818 may include a chuck, a fork, or lift pins (not shown) to hold and transfer the substrate 816 into and out of the chamber 824 between operations. The chuck may be an electrostatic chuck, a mechanical chuck, or various other types of chuck as are available for use in the industry and/or for research.

Various process gases may be introduced via inlet 812, such as carrier gases or other precursor-free gases. Multiple source gas lines 810 are connected to manifold 808. The gases may be premixed or not. Appropriate valving and mass flow control mechanisms may be employed to ensure that the correct process gases are delivered during the deposition and plasma treatment phases of the process. In the case where a chemical precursor(s) is delivered in liquid form, liquid flow control mechanisms may be employed. Such liquids may then be vaporized and mixed with process gases during transportation in a manifold heated above the vaporization point of the chemical precursor supplied in liquid form before reaching the deposition chamber 824.

Process gases may exit chamber 824 via an outlet 822. A vacuum pump, e.g., a one or two stage mechanical dry pump and/or turbomolecular pump 840, may be used to draw process gases out of the process chamber 824 and to maintain a suitably low pressure within the process chamber 824 by using a closed-loop-controlled flow restriction device, such as a throttle valve or a pendulum valve. The vacuum pump may also purge gases and particles out of the process chamber 824 during methods described herein.

As discussed above, the techniques for RF cycling discussed herein may be implemented on a multi-station or single station tool. In one example, deposition of a conformal film, such as titanium oxide, occurs on a wafer in a first station station and upon indexing the wafers and transferring the wafer with the deposited conformal film to another station, RF pulsing may occur at the first station. In specific implementations, a 300 mm Lam Vector™ tool having a 4-station deposition scheme or a 200 mm Sequel™ tool having a 6-station deposition scheme may be used. In some implementations, tools for processing 450 mm wafers may be used. In various implementations, the wafers may be indexed after every deposition and/or every RF cycling process, or may be indexed after etching steps if the etching chambers or stations are also part of the same tool, or multiple depositions and RF cycling may be conducted at a single station before indexing the wafer.

In some embodiments, an apparatus may be provided that is configured to perform the techniques described herein. A suitable apparatus may include hardware for performing various process operations as well as a system controller 830 having instructions for controlling process operations in accordance with the disclosed embodiments. The system controller 830 will typically include one or more memory devices and one or more processors communicatively connected with various process control equipment, e.g., valves, RF generators, wafer handling systems, etc., and configured to execute the instructions so that the apparatus will perform a technique in accordance with the disclosed embodiments, e.g., a technique such as that provided in the operations of FIGS. 7A and 7B. Machine-readable media containing instructions for controlling process operations in accordance with the present disclosure may be coupled to the system controller 830. The controller 830 may be communicatively connected with various hardware devices, e.g., mass flow controllers, valves, RF generators, vacuum pumps, etc. to facilitate control of the various process parameters that are associated with the deposition operations as described herein.

In some embodiments, a system controller 830 may control all of the activities of the reactor 800. The system controller 830 may execute system control software stored in a mass storage device, loaded into a memory device, and executed on a processor. The system control software may include instructions for controlling the timing of gas flows, wafer movement, RF generator activation, etc., as well as instructions for controlling the mixture of gases, the chamber and/or station pressure, the chamber and/or station temperature, the pedestal temperature, the target power levels, the RF power levels, the substrate pedestal, chuck, and/or susceptor position, and other parameters of a particular process performed by the reactor apparatus 800. The system control software may be configured in any suitable way. For example, various process tool component subroutines or control objects may be written to control operation of the process tool components necessary to carry out various process tool processes. The system control software may be coded in any suitable computer readable programming language.

The system controller 830 may typically include one or more memory devices and one or more processors configured to execute the instructions so that the apparatus will perform a technique in accordance with the present disclosure. Machine-readable media containing instructions for controlling process operations in accordance with disclosed embodiments may be coupled to the system controller 830.

The method and apparatus described herein may be used in conjunction with lithographic patterning tools or processes such as those described below for fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step performed with a number of possible tools: (1) application of photoresist on a workpiece using a spin-on or spray-on tool; (2) curing a photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferred the resist pattern into an underlying film or workpiece by using a dry or plasma-assisted etching tool such as those described below; and (6) removing the resist using a tool such as an RF or microwave plasma resist stripper.

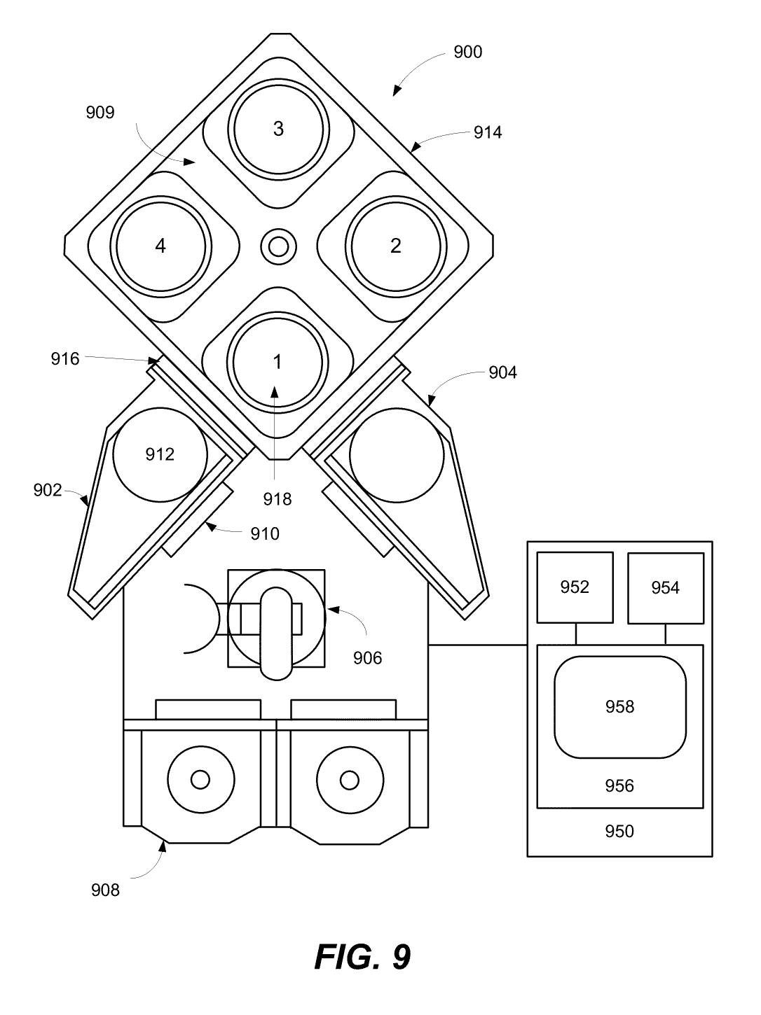

One or more process stations may be included in a multi-station processing tool. FIG. 9 shows a schematic view of an embodiment of a multi-station processing tool 900 with an inbound load lock 902 and an outbound load lock 904, either or both of which may include a remote plasma source. A robot 906, at atmospheric pressure, is configured to move wafers from a cassette loaded through a pod 908 into inbound load lock 902 via an atmospheric port 910. A wafer is placed by the robot 906 on a pedestal 912 in the inbound load lock 902, the atmospheric port 910 is closed, and the load lock is pumped down. Where the inbound load lock 902 includes a remote plasma source, the wafer may be exposed to a remote plasma treatment in the load lock prior to being introduced into a processing chamber 914, such as before deposition of a conformal film onto the wafer. Further, the wafer also may be heated in the inbound load lock 902 as well, for example, to remove moisture and adsorbed gases. Next, a chamber transport port 916 to processing chamber 914 is opened, and another robot (not shown) places the wafer into the reactor on a pedestal of a first station shown in the reactor for processing. While the embodiment depicted includes load locks, it will be appreciated that, in some embodiments, direct entry of a wafer into a process station may be provided.

The depicted processing chamber 914 includes four process stations, numbered from 1 to 4 in the embodiment shown in FIG. 9. Each station may have a heated pedestal (shown at 918 for station 1), and gas line inlets. It will be appreciated that in some embodiments, each process station may have different or multiple purposes. For example, in some embodiments, a process station may be switchable between a CFD (or PEALD) and PECVD process mode. Additionally or alternatively, in some embodiments, processing chamber 914 may include one or more matched pairs of CFD (or PEALD) and PECVD process stations. In some embodiments, a process station may be used for depositing a conformal film on a wafer. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 also depicts an embodiment of a wafer handling system 990 for transferring wafers within processing chamber 914. In some embodiments, wafer handling system 990 may transfer wafers between various process stations and/or between a process station and a load lock. It will be appreciated that any suitable wafer handling system 990 may be employed. Non-limiting examples include wafer carousels and wafer handling robots. FIG. 9 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog and/or digital input/output connections, stepper motor controller boards, etc.

In some embodiments, system controller 950 controls all of the activities of process tool 900. System controller 950 executes system control software 958 stored in mass storage device 954, loaded into memory device 956, and executed on processor 952. Alternatively, the control logic may be hard coded in the controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, chamber and/or station pressure, chamber and/or station temperature, showerhead temperature, target power levels, RF power levels, RF exposure time, substrate pedestal, chuck and/or susceptor position, and other parameters of a particular process performed by process tool 900. System control software 958 may be configured in any suitable way. For example, various process tool component subroutines or control objects may be written to control operation of the process tool components necessary to carry out various process tool processes. System control software 958 may be coded in any suitable computer readable programming language.

In some embodiments, system control software 958 may include input/output control (IOC) sequencing instructions for controlling the various parameters described above. For example, introducing a precursor-free gas and igniting a plasma may include one or more instructions for execution by system controller 950. The instructions for setting process conditions for RF purging may be included in a corresponding RF purging recipe phase. In some embodiments, the RF purging recipe phases may be sequentially arranged, so that all instructions for a RF purging process phase are executed concurrently with that process phase.

Other computer software and/or programs stored on mass storage device 954 and/or memory device 956 associated with system controller 950 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 918 and to control the spacing between the substrate and other parts of process tool 900.

A process gas control program may include code for controlling gas composition and flow rates and optionally for flowing gas into one or more process stations prior to deposition in order to stabilize the pressure in the process station. In some embodiments, the controller 950 includes instructions for introducing a precursor-free gas into the chamber 914 through the showerhead and igniting a plasma during, after, or before introducing the precursor-free gas.

A pressure control program may include code for controlling the pressure in the process station by regulating, for example, a throttle valve in the exhaust system of the process station, a gas flow into the process station, etc. In some embodiments, the controller 950 includes instructions for introducing a precursor-free gas into the chamber 914 through the showerhead and igniting a plasma during, after, or before introducing the precursor-free gas.

An optional heater control program may include code for controlling the current to a heating unit that is used to heat the substrate. Alternatively, the heater control program may control delivery of a heat transfer gas (such as helium) to the substrate.

A plasma control program may include code for setting RF power levels and exposure times in one or more process stations in accordance with the embodiments herein. In some embodiments, the controller 950 includes instructions for introducing a precursor-free gas into the chamber 914 through the showerhead and igniting a plasma during, after, or before introducing the precursor-free gas. The plasma may be pulsed while the precursor-free gas is introduced into the chamber 914, or may be ignited before or after introducing the precursor-free gas into the chamber 914.

In some embodiments, there may be a user interface associated with system controller 950. The user interface may include a display screen, graphical software displays of the apparatus and/or process conditions, and user input devices such as pointing devices, keyboards, touch screens, microphones, etc.

In some embodiments, parameters adjusted by system controller 950 may relate to process conditions. Non-limiting examples include process gas composition and flow rates, temperature, pressure, plasma conditions (such as RF bias power levels and exposure times), etc. These parameters may be provided to the user in the form of a recipe, which may be entered utilizing the user interface.

Signals for monitoring the process may be provided by analog and/or digital input connections of system controller 950 from various process tool sensors. The signals for controlling the process may be output on the analog and digital output connections of process tool 900. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 950 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 950 will typically include one or more memory devices and one or more processors configured to execute the instructions so that the apparatus will perform a method in accordance with the disclosed embodiments. Machine-readable, non-transitory media containing instructions for controlling process operations in accordance with the disclosed embodiments may be coupled to the system controller 950.

Experimental

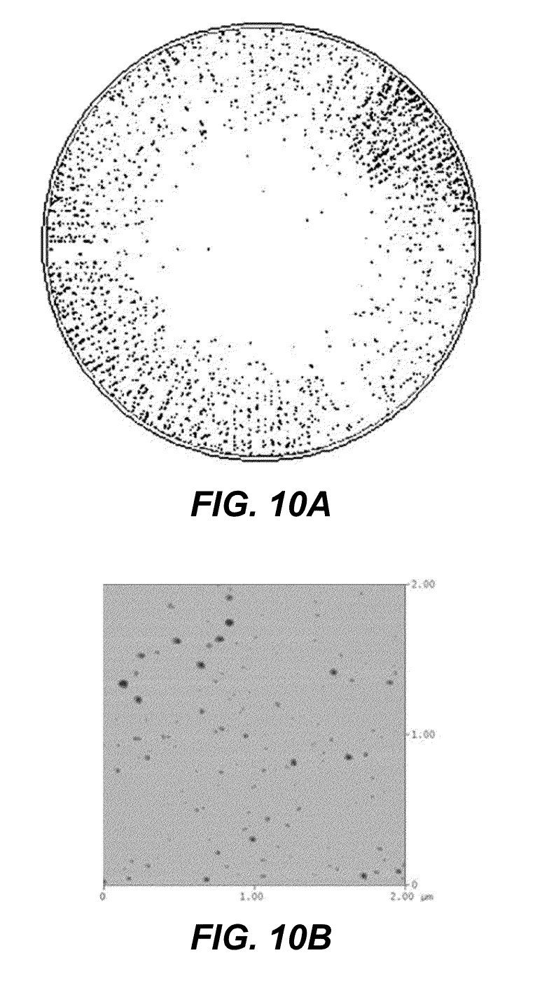

An experiment was conducted to evaluate the presence of particles on a wafer before and after radio frequency (RF) cycling in accordance with disclosed embodiments. A layer of titanium oxide film was deposited by atomic layer deposition (ALD) on a substrate. A mechanical cycle gas-only particle wafer check without RF cycle purging was conducted. An image of the particles on the wafer is shown in FIG. 10A. An atomic force microscopy (AFM) image of the film processed without RF cycle purging is shown in FIG. 10B. The shading of the images in 10A and 10B are inverted to show the particles as black dots. RMS roughness was measured to be 11.69 Å. The particle count was over 4000, as shown in Table 1.

TABLE 1
Particle Wafer Check without RF Cycle Purging

| Particle Bin Size | Particle Count |
|---|---|
| 0.04-0.05 | 591 |
| 0.05-0.06 | 352 |
| 0.06-0.08 | 714 |
| 0.08-0.1 | 492 |
| 0.1-0.1225 | 315 |
| >0.1225 | 1543 |
| Total | 4007 |

A layer of titanium oxide film was deposited by ALD on a substrate after RF cycle purging for one hour. The conditions for the RF cycle purging are shown in Table 2.

TABLE 2
RF Cycling Conditions

| | | |
|---|---|---|
| RF Power | 2500 | W |
| Process Pressure | 3.5 | Torr |

| Cycle | Time (s) |
|---|---|
| Dose (no precursor) | 0.5 |
| Purge | 0.5 |
| RF ON | 0.5 |
| Purge | 0.5 |

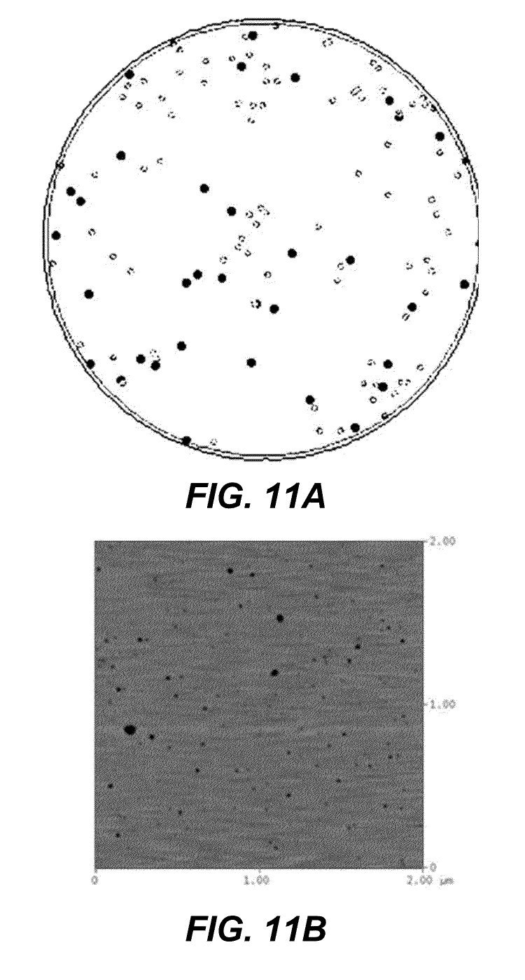

A mechanical cycle gas-only particle wafer check with RF cycle purging was conducted. An image of the particles on the wafer is shown in FIG. 11A. The image shows substantially fewer particles than in FIG. 10A. An atomic force microscopy (AFM) image of the film processed without RF cycle purging is shown in FIG. 11B. The shading of the images in 11A and 11B are inverted to show the particles as black dots. RMS roughness was measured to be 4.5 Å. The particle count was 126, as shown in Table 3. Note the number of particles is substantially decreased compared to the wafer without RF cycle purging.

TABLE 3
Particle Wafer Check with RF Cycle Purging

| Particle Bin Size | Particle Count |
|---|---|
| 0.04-0.05 | 12 |
| 0.05-0.06 | 5 |
| 0.06-0.08 | 10 |
| 0.08-0.1 | 3 |
| 0.1-0.1225 | 5 |
| >0.1225 | 91 |
| Total | 126 |

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems and apparatus of the present embodiments. Accordingly, the present embodiments are to be considered as illustrative and not restrictive, and the embodiments are not to be limited to the details given herein.

1. A method of processing semiconductor substrates in a process chamber with a showerhead, the method comprising:
after depositing a film on one or more substrates in the process chamber, performing a precursor-free radio frequency (RF) cycle purge without a substrate in the process chamber by introducing a gas without a precursor into the process chamber through the showerhead and igniting a plasma one or more times,
wherein depositing the film comprises introducing a vaporized liquid precursor into the process chamber through the showerhead.

2. The method of claim 1, wherein the vaporized liquid precursor has a viscosity greater than about 10 cP.

3. The method of claim 1, wherein at least one of the one or more substrates comprises titanium oxide and the vaporized liquid precursor is TDMAT.

4. The method of claim 1, wherein at least one of the one or more substrates comprises titanium oxide and the vaporized liquid precursor is titanium isopropoxide.

5. The method of claim 1, wherein the gas is selected from the group consisting of nitrogen (N₂), helium (He), hydrogen (H₂), nitrous oxide (N₂O), and oxygen (O₂).

6. The method of claim 1, wherein the substrate is processed at a chamber pressure between about 1 Torr and 4 Torr.

7. The method of claim 1, wherein the substrate is processed at a temperature between about 50° C. and about 400° C.

8. The method of claim 1, wherein the plasma is ignited by a radio frequency having a high frequency component power per substrate area of between about 0.018 W/cm² and about 0.884 W/cm² and a low frequency component power per substrate area of between about 0 W/cm² and about 0.884 W/cm².

9. The method of claim 1, wherein the gas is introduced for between about 0.25 seconds and about 10 seconds.

10. The method of claim 1, wherein plasma is ignited for a time between about 0.25 seconds and about 10 seconds.

11. The method of claim 1, wherein depositing the film further comprises igniting the plasma.

12. The method of claim 11, wherein the RF power of the plasma ignited while depositing the film is the same as the RF power of the plasma ignited while performing the precursor-free RF cycle purge.

13. An apparatus for processing semiconductor substrates, the apparatus comprising:
one or more process chambers, each chamber comprising a showerhead and a pedestal;
one or more gas inlets into the process chambers and associated flow-control hardware;
a radio frequency (RF) generator; and
a controller having at least one processor and a memory,
wherein the at least one processor and the memory are communicatively connected with one another,
the at least one processor is at least operatively connected with the flow-control hardware and RF generator, and
the memory stores computer-executable instructions for:
after introducing a vaporized liquid precursor to at least one of the one or more process chambers, introducing a gas without a precursor into the at least one of the one or more process chambers through the showerhead, and
periodically igniting a plasma.

14. The apparatus of claim 13, wherein the memory further comprises instructions for igniting the plasma by a radio frequency having a high frequency component power per substrate area of between about 0.018 W/cm² and about 0.884 W/cm² and a low frequency component power per substrate area of between about 0 W/cm² and about 0.884 W/cm².

15. The apparatus of claim 13, wherein the gas is selected from the group consisting of nitrogen (N₂), helium (He), hydrogen (H₂), nitrous oxide (N₂O), and oxygen (O₂).

16. The apparatus of claim 13, wherein the vaporized liquid precursor is TDMAT.

17. The apparatus of claim 13, wherein the memory further comprises instructions for introducing the gas for a time between about 0.25 seconds and about 10 seconds.

18. The apparatus of claim 13, wherein the memory further comprises instructions for igniting the plasma for a time between about 0.25 seconds and about 10 seconds.
